(19) United States
(12) Patent Application Publication
(10) Pub. No.: US 2026/0086149 A1
(43) Pub. Date: Mar. 26, 2026

(54) CLOSED LOOP ADAPTIVE GENERATIVE ADVERSARILY NETWORK FILTER

(71) Applicant: Tektronix, Inc., Beaverton, OR (US)

(72) Inventors: Keith R. Tinsley, Eugene, OR (US); David M. Bouse, Camas, WA (US); Sarah R. Boen, Portland, OR (US); Josiah A. Bartlett, Forest Grove, OR (US)

(21) Appl. No.: 19/303,995

(22) Filed: Aug. 19, 2025

Related U.S. Application Data
(60) Provisional application No. 63/699,259, filed on Sep. 26, 2024.

(51) Int. Cl. G01R 31/319; G01R 31/317

(52) U.S. Cl. CPC G01R 31/319; G01R 31/31708

(57) ABSTRACT

A test and measurement system includes a plurality of nodes, one or more nodes comprising sensors configured to receive signals, one or more generative adversarial network (GAN) models, one or more signal generators configured to generate and transmit signals, and one or more processors configured to execute code to cause the one or more processors to receive a request for a signal having a signal profile from a node of the plurality of nodes, send the signal profile and the request to one of the one or more GAN models, receive a matching signal profile that matches the signal profile, and transmit the matching signal profile to one of the one or more signal generators to generate and transmit a matching signal.

### CROSS-REFERENCE TO RELATED APPLICATIONS

This disclosure is a non-provisional of and claims benefit from U.S. Provisional Application No. 63/699,259, titled “CLOSED LOOP ADAPTIVE GENERATIVE ADVERSARILY NETWORK FILTER,” filed on Sep. 26, 2024, the disclosure of which is incorporated herein by reference in its entirety.

### TECHNICAL FIELD

This disclosure relates to test and measurement instruments, and more particularly to artificial intelligence to generate waveforms for test and measurement instruments and environments.

### BACKGROUND

Waveforms, the graph of a signal over time, have many different functions in electronics testing. Devices under test (DUTs) generate signals that form the waveforms, allowing analysis of the performance of the devices. The DUT may generate signals in response to a signal being applied to the DUT. Some test instruments, such as arbitrary waveform generators and arbitrary function generators, generate and apply the signals.

In many instances, providing these waveform generation products with the ability to produce different types of waveforms with specific characteristics involves updating the embedded software in these devices. Further, some aspects of the produced signals may not account for the effects of an unknown channel or unknown environment that on the signal.

The ability to replicate signals from DUTs and generate signals that have specific environmental and channel conditions can provide flexibility and precision not previously attainable.

### BRIEF DESCRIPTION OF THE DRAWINGS

FIG. 1 shows a system diagram of an artificial intelligence-based system for test and measurement.

FIG. 2 shows a flow diagram for an embodiment of a closed loop optimization test and measurement system.

FIG. 3 shows an embodiment of a sensor node comprising a test and measurement instrument.

FIG. 4 shows an embodiment of a node during a receiving process.

FIG. 5 shows an embodiment of a node during a transmitting process.

FIG. 6 shows a flowchart of an embodiment of a method to generate a matching signal.

FIG. 7 shows an embodiment of an artificial intelligence-based system for test and measurement in a specific environment.

### DESCRIPTION

The embodiments herein involve a test and measurement system comprised of a network of nodes, one or more central servers, and a database. Some embodiments may include a large language model (LLM) interface to the database. Some embodiments have nodes comprised of test and measurement instruments. Most, if not all, nodes have processing capability that allows the node to operate a generative adversarial network (GAN). The nodes with processing capabilities may also be configured to employ federated learning.

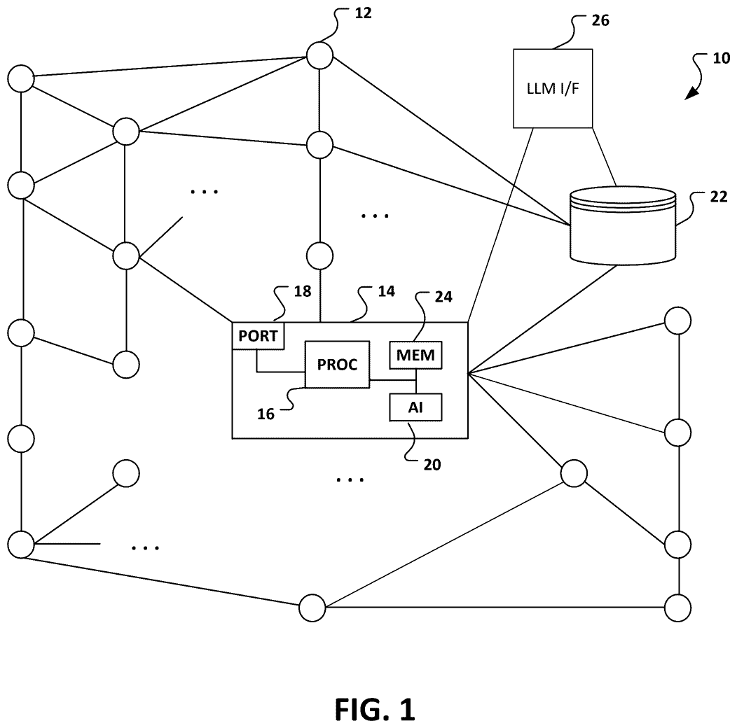

FIG. 1 shows an embodiment of the test and measurement system. System 10 includes a network of nodes, like node 12, one or more servers like server 14, and one or more databases like database 22. The server 14 may be referred to as a “centralized server” meaning that the server 14 communicates with many, if not all, of the nodes 12, not the physical location of the server 14. The server 14, as well as any nodes 12 that comprise a test and measurement device, may comprise one or more processors 16, a memory 24, a port 18 that allows the server 14 or node 12 to communicate with a device under test (DUT), and a machine learning system 20. Machine learning system 20 may comprise a separate processor from a main processor that has undergone programming to operate a machine learning process, both of which are represented by processor 16.

For purposes of this discussion, the term “artificial intelligence” (AI) refers to machine learning, meaning a neural network or other machine learning architecture that has undergone training, supervised or unsupervised, to produce an output, and “generative AI.” Generative AI may comprise a large language model (LLM) and include a transformer. Generative AI may also refer to GANs that are more than likely operating without a transformer.

GANs typically comprise two neural networks. One network, the generative network or generator, produces an output that mimics an input. The other network, the discriminative network or discriminator, evaluates the output and determines if the output truly mimics the input. The two networks “compete” with the other until the discriminator “loses” because the output mimics the input so closely that the discriminator cannot tell the difference, typically determined by an error process. As used here the term “GAN model” or “GAN” refers to a pair of neural networks. Multiple GAN models, meaning multiple pairs of neural networks, may exist in AI 20.

The system 10 of FIG. 1 employs federated learning, where the base or “bootstrap” model of the GAN resides on most, if not all, of the system. Some nodes 12 in the system 10 may comprise transport or other types of nodes that do not operate on inputs and outputs. These nodes route data or handle other tasks that do not involve reception or transmission of signals external to the system 10. This discussion refers to nodes that receive signals as receiver nodes, and nodes the transmit signals external to the system as transmitter nodes. Many nodes may be both receiver and transmitter nodes.

Just as an example for ease of understanding, node 12 in system 10 may comprise a sensor node that receives a signal. As a waveform results from a signal overtime, the terms “signal” and “waveform” are used interchangeably. The signal may comprise a signal from a DUT, or could comprise a “threat” signal, such as an incoming radar signal. Node 12 receives the signal and generates a response. The response may comprise replicating the signal with a GAN and deriving the environment and channel characteristics from the replication process.

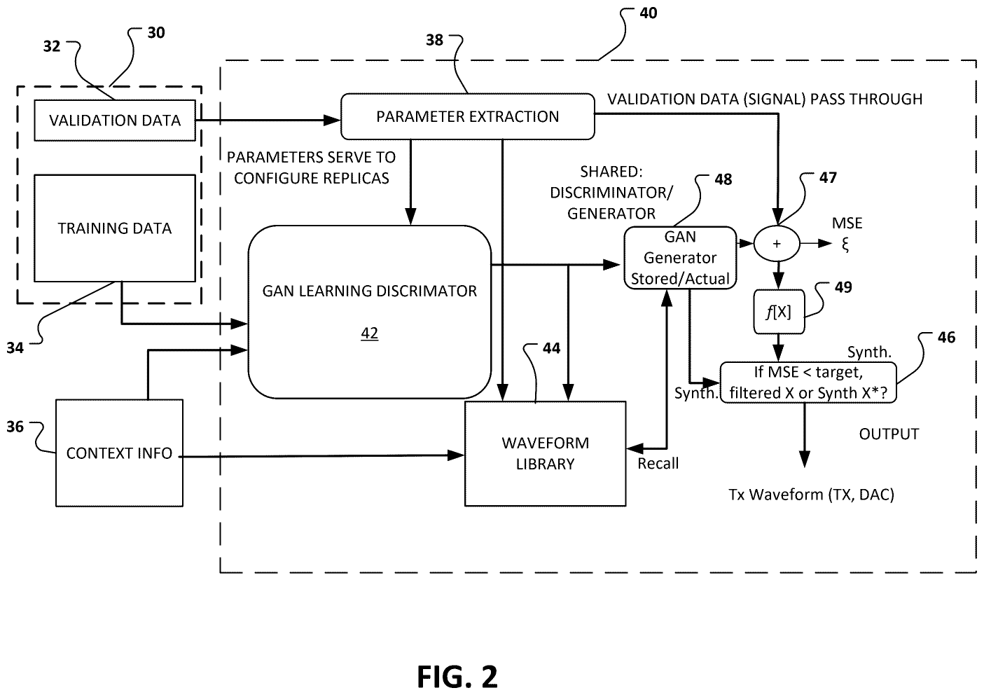

FIG. 2 shows an embodiment of the various elements of the AI components within AI component 20 and their interactions. As discussed above, the AI component 20 may reside on the server 14 and on multiple nodes within the system 10 of FIG. 1. The process has a receive side 30 and a transmit side 40. On the receive side 30, input signal data received at a sensor becomes training data 34 possibly coupled with the validation data 32. The validation data 32 may be received through data sampling of the DUT environment directly, referred to here as online, or through file uploads, referred to here as off-line. The training data 34 and context information 36 become inputs to the GAN learning discriminator 42. Context information 36 may include the environment in which the receiving node resides, specifics of the node characteristics, such as the node's processing capability, role, etc., and the nature of the received signal, such as from a DUT, an external source. The GAN learning discriminator 42 receives the training data 34, the context information 36, and the parameters 39 extracted from the validation data 32. The GAN learning discriminator 42 then configures what the replicas of the received signal should look like.

The incoming data from receive side 30 may pass through the parameter extraction module 38 and be stored in the waveform library 44. The incoming data 32 and/or 34 may be digitally affixed or encoded, such as water marking. The waveform library 44 may also include context information 36. GAN generator 48 may receive the received waveform from the waveform library 44 if the replication/transmission process occurs sequentially with the received signal. When the received signal does not require a response, the system may store the signal for later use, relying upon the encoding for systematic, rapid retrieval.

Whenever a response is to occur, the GAN generator 48 may use a stored waveform, or, in the case of a sequential response, the actual response waveform. GAN generator 48 produces a candidate signal based upon the incoming, received signal. The candidate signal produced by the GAN generator 48 may comprise a replica of the incoming signal, a replica with the incoming signal but with variations of some of the characteristics, or may be an inverse of the signal, such as may be used in electronic warfare to “cancel” the incoming signal. The characteristics of the signal may also be referred to as the signal profile. The generated signal is then compared to the validation data 32 of the received signal passed through parameter extraction 38 without alteration at comparator 47.

The comparison may employ an error measurement such as the mean squared error (MSE), or other error measurement. An optimization function applied at comparator 47 governs the error measurement. Optimization functions generally find the best possible solution, typically a maximum or a minimum. The optimization function defines an objective function that evaluates candidate solution and finds the input that yields the most desirable output. In this case, the object function minimizes the error between the ‘real’ and synthesized waveform. If the synthesized waveform has too high an error measurement, the “real” waveform from the received signal may be selected. If the real waveform will not suffice, because the desired waveform is an inverse or some other variation of the real waveform, the data may be mixed between the real and synthesized waveform until the desired performance metric is met.

The error measurement may comprise, but is not limited to, mean squared error, mean absolute error, root mean squared error, R-squared, adjusted R-squared, mean squared logarithmic error, and median absolute deviation. The process may use any of these error measurements to evaluate the GAN model accuracy. The generated, or “synthesized” signal, also undergoes filtering at filter 49 to adjust for the errors detected in the comparison. The unfiltered synthesized signal or the filtered signal is then selected at selector 46 depending upon the error measure and output.

The output signal may then be transmitted if the generated signal requires transmission. Alternatively, the output signal could be applied to a DUT. The signal being applied to the DUT may occur when the DUT is undergoing testing, and no signal was originally received, the DUT just has a testing need that requires a waveform with particular characteristics.

The synthesized signal from the GAN generator 48 may be stored in the waveform library 44 with the associated error measurement if the synthesized signal is selected at selector 46. The error measurement may be included with the waveform to be used as selection criterion in the waveform library 44.

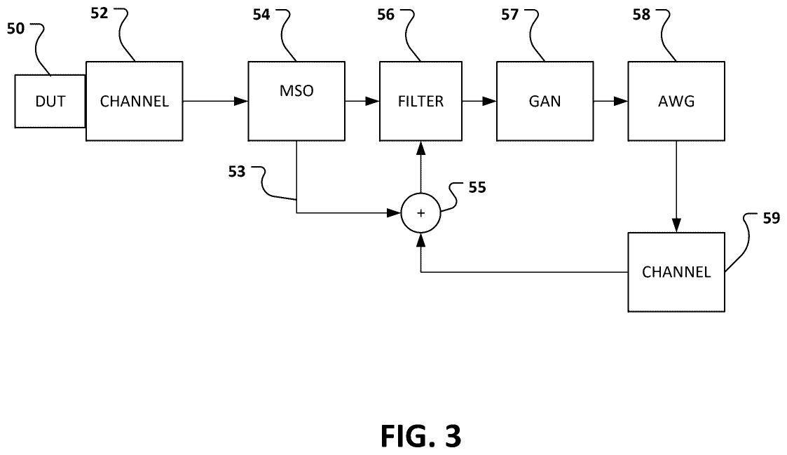

FIG. 3 shows an example of a node that may reside in the network show in FIG. 1 that comprises a test and measurement instrument. In one embodiment, the node may employ a GAN to replicate a signal within the instrument. The test and measurement instrument may comprise a “compound” instrument, meaning that the instrument comprises two different instruments. In the embodiment of FIG. 3, the compound instrument comprises a mixed-signal oscilloscope (MSO) 54 and an arbitrary waveform generator (AWG) 58. The term AWG as used here includes both arbitrary waveform generators and arbitrary function generators.

DUT 50 connects to MSO 54 through one or more channels 52. In this embodiment, channel 52 is unknown in that channel 52 has unknown characteristics. The DUT 50 produces a signal that passes through channel 52 to MSO 54. MSO 54 receives the signal on channel 52 and copies the signal on channel 53. The incoming signal on the first channel 52 undergoes signal processing and conditioning in MSO 54. This conditioning may include conversion from analog to digital, signal conditioning, timing adjustments, etc. The signal from the first channel 52 is then undergoes filtering at filter 56 and then is then replicated by the GAN 57. The GAN 57 iterates between themselves until the discriminator determines that the generator has generated a replica indistinguishable from the first. The iterations of the GAN 57 result in a signal for the “calibrated” channel 59. The AWG 58 then takes the signal from the GAN 57 and produces another signal on the channel 59. The signal on channel 59 is compared to the “original” signal that came in on channel 52 that passes through the MSO to channel 53 that goes to comparator 55 and the results may be used to adjust the filter 56 to remove the differences or otherwise alter the original signal if desired. The results of the comparison may also be used to produce the characteristics of channel 52 from the calibration process. This channel characterization and the original signal may then be stored in the waveform library 22 of FIG. 1, or 44 of FIG. 2.

As mentioned above, the nodes in the system that have the capability to operate a GAN may participate in federated learning. In federated learning, each node, as the GAN model(s) on that node undergoes tuning and changing through the discriminator process, may broadcast the updates to the bootstrap model on that node. Each other node in the system does the same, resulting in all nodes in the system that are operating GANs having at least the capability to update themselves to put all the nodes into parity regarding their models. In some embodiments, different nodes may have different federated learning policies in place that only accept selected updates and reject all others, or in the reverse, only reject certain updates but accept all others.

The updated nodes also transmit their updates to the central or main server(s) to update the models that reside on the server(s). When a new node comes into service in the system, the updating process at the server(s) may allow that node to receive the most updated version of the model. That node may also receive the bootstrap model and then the updates, to allow the node to filter those updates that are not relevant to that node.

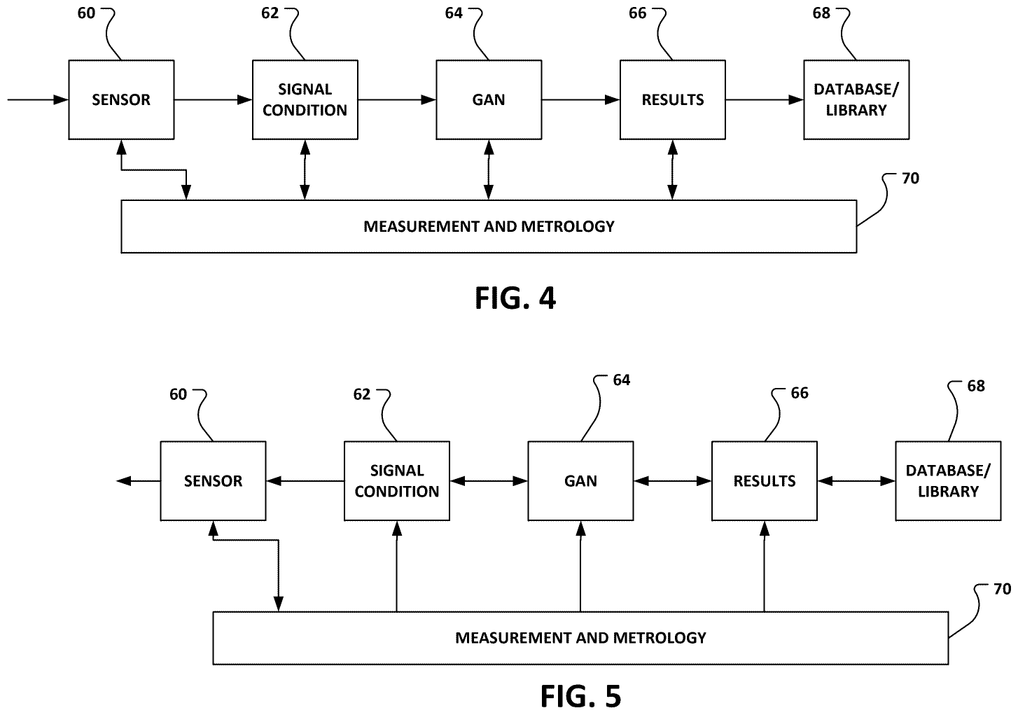

FIGS. 4 and 5 show more generalized versions of the nodes on both the receive process in FIG. 4 and the transmit process in FIG. 5. In the receive process in FIG. 4, a sensor node 60 receives the incoming signal and captures characteristics of the DUT, the environment under test (EUT), and the channel under test in which the signal was received and provides those to the model on the node. The signal undergoes conditioning via a signal conditioner 62 and the GAN 64 operates to ensure the replication of the signal is as close to the original as possible. The results 66 are then made available for analysis by whomever needs to see them, and the resulting replication, which may include inverse signals, signals with variants from the original signal, etc., and then stored in the waveform database 68. The waveform database 68 may constitute a library as will be discussed below. Measurement and metrology module 70 allows the sensor node 60 to make measurements on the incoming signal, break down the components and/or characteristics of the signal as desired, as well as monitor the performance of the GAN 64. The measurement and metrology module may interact with the other modules as needed depending upon the results of measurements, such as communicating with the sensor if the information was not received completely or other issues with the signal. Module 70 may also communicate with the signal conditioning module if the nature of the signal requires adjustments to the signal conditioning. As the GAN 64 operates, the results from module 70 may change, requiring updating of the results, so modules 70 and 66 may pass the results back and forth until the results are ready to be stored.

FIG. 5 shows the transmit process. When a request for a signal is received, either in response to an incoming signal or for testing of a DUT, EUT or channel, the node or central server of FIG. 1 accesses the database/library 68 and provides the desired version of the signal via results 66. The signal is then provided to GAN 64 with any particular characteristics needed and the GAN 64 operates to produce the desired signal. The signal undergoes any conditioning, such as conversion from digital back to analog, at signal conditioner 62 and the signal is provided to the sensor node 60 for use by an AWG on the sensor to generate and transmit the signal.

As mentioned above, any resulting changes or updates to the GAN model may be distributed to the other nodes as part of the federated learning environment.

With the development and population of the waveform database, one could employ the waveform database 22 like a library used by large language models. Returning to FIG. 1, a large-language model (LLM) interface 26 allows a user to enter a prompt for development of a particular waveform needed. The test environment from which the prompt comes, as well as the characteristics of the waveform specified by the user, can be converted to an LLM-type vector. The LLM vector is then used to access the waveform library to find a matching signal, or to find signals that approximate the signal upon which the GAN models can operate to generate the desired waveform.

This disclosure encompasses the concept related to the creation of waveforms through a learned large waveform model (LWM). This embodiment utilizes artificial intelligence or machine learning to train a model based on uploaded data applicable to the targeted experiment. The waveform produced is based on contextual awareness of the communicated test environment. The interface used to query can be done through various interfaces, not solely due to a keyboard.

The distributed learning that empowers the embodiments is based on principles for distributed learning, including, but not limited to, federated learning, having an application programming interface (API) that allows for direct translation, loading, or sequences of waveforms to deliver streaming physical data that interacts with a medium of communication, e.g., air, water, etc.

This disclosure solves the problem of rapid prototyping of waveforms for stimulus on targeted devices under test (DUTs), giving a unified format for executing agnostic waveform translators used to export signals into the real world. In addition, users benefit from other participants who allow them to share their learned waveforms derived from their shared measured data, uploaded to the platform, to further train the associated LWM. The LWM may be public or private and may be as specific as being associated with the sole industry and its participants.

Dynamic waveform prototyping with direct memory through the LLM interface assists the platform in learning optimal waveforms based on the context provided through the LLM interface. Based on the contextual data provided, the learned waveforms may be tagged and grouped based on customers' unique DUT environments. This capability does not exist at the time of this disclosure.

In one embodiment, the user interface into the test and measurement system comprises a large-language model interface. In the embodiment using the large-language model interface, the provided waveforms are tagged with metadata to allow for updating of the library with the new model.

In this manner a test and measurement system can receive and produce signals/waveforms as needed with the employment of machine learning to ensure accuracy and matching to the desired signal profile.

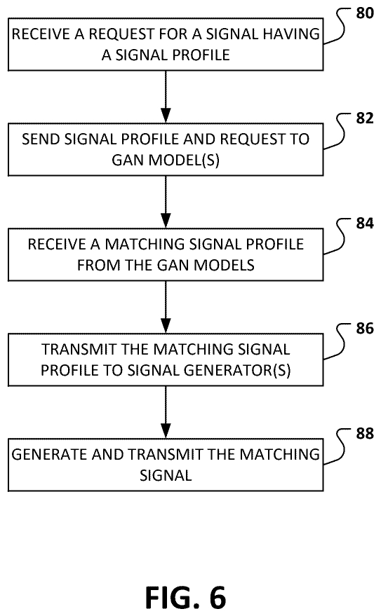

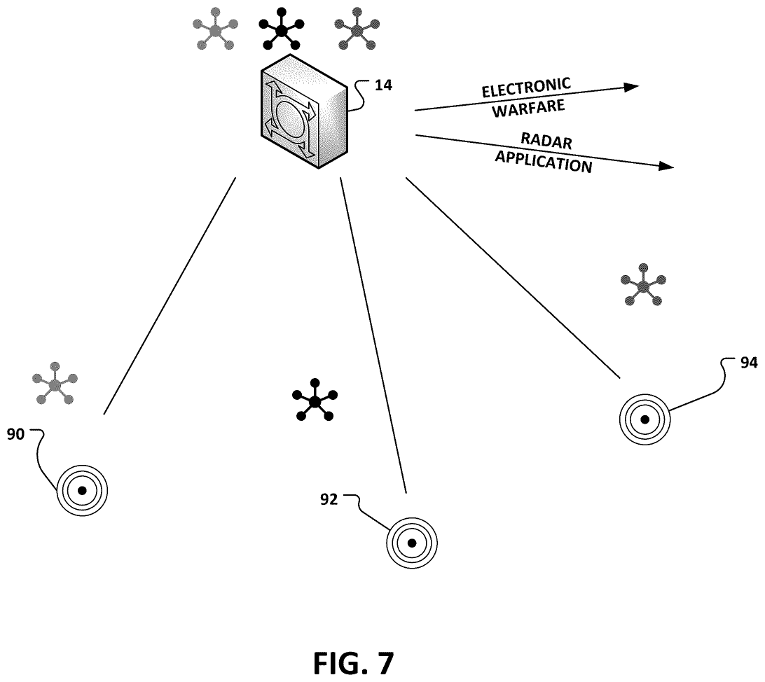

As an example of an application of this system, FIGS. 6 and 7 show a flowchart of an embodiment of a method of generating a matching signal from a received signal, and diagram of the nodes in a specific embodiment of a threat environment. For example, a sensor node, 90, 92, or 94 in FIG. 7, may receive a test signal representing a threat signal. The system takes the received signal and determines a response. Depending upon the capabilities of the node (e.g., sensor node 90, 92, 94), the response may come from the node, the central server 14, if the node does not have the capability needed to respond.

In any of the above situations, the node generates a request at 80 in FIG. 6 for a signal having a signal profile that includes information about the signal, the environment in which the node is operating, metadata information related to the signal, possibly the target of the matching signal to be sent, and the information captured above, as examples without limitation. The request is sent to the one or more GAN models, as discussed above at 82, which can be models on the node, from the node to the central server in turn to the GAN models, to neighboring nodes with that capability, all of which here are referred to as the requester. The requester then receives a matching signal profile from the one or more GAN models at 84. The requester sends the matching signal profile to one or more signal generators at 86. In an optional process, at 88 a signal generator then may generate and transmit the signal to the node, so the node may transmit the matching signal to the received signal as needed.

One aspect of the response is a countermeasure signal, for electronic warfare, to disrupt the incoming signal. The other aspect may comprise a radar signal sent to determine the location of the signal source. The received signal undergoes conditioning, and two signals may be produced, both replicas in some manner of the received signal. The system generates replicas from the base signal and access to the waveform library/data base, and the resulting signals are sent by an AWG within the system. The above discussion constitutes one example, without limitation to any particular embodiments used here.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.
Example 1 is a test and measurement system, comprising: a plurality of nodes, one or more nodes comprising sensors configured to receive signals; one or more generative adversarial network (GAN) models; one or more signal generators configured to generate and transmit signals ; and one or more processors configured to execute code to cause the one or more processors to: receive a request for a signal having a signal profile from a node of the plurality of nodes; send the signal profile and the request to one of the one or more GAN models; receive a matching signal profile that matches the signal profile; and transmit the matching signal profile to one of the one or more signal generators to generate and transmit a matching signal.
Example 2 is the test and measurement system of Example1, wherein the signal profile includes one or more of an environment in which a node of the plurality of nodes operates, metadata of the request, and a potential target of the matching signal.
Example 3 is the test and measurement system of either of Examples 1 or 2, wherein the one or more processors are further configured to store the matching signal in a database.
Example 4 is the test and measurement system of Example 3, wherein the one or more processors are further configured to access the database to determine if the signal profile exists in the database, and to send the signal profile from the database to the one or more GAN models.
Example 5 is the test and measurement system of any of Examples 1 through 4, wherein the one or more processors are further configured to operate the one or more GAN models to produce the matching signal profile.
Example 6 is the test and measurement system of any of Examples 1 through 5, wherein the one or more processors configured to operate the one or more GAN models comprises one or more processors on a node of the plurality of nodes that sent the request.
Example 7 is the test and measurement system of any of Examples 1 through 6, wherein the one or more processors configured to operate the one or more GAN models comprises one or more processors on a central server in the test and measurement system.
Example 8 is the test and measurement system of Example 7, wherein the one or more processors on the central server are further configured to distribute an updated GAN model resulting from the request to the plurality of nodes.
Example 9 is the test and measurement system of any of Examples 1 through 8, wherein one or more of the sensors receives an incoming signal from a device under test (DUT).
Example 10 is the test and measurement system of Example 9, wherein one or more of the sensors further comprises a test and measurement instrument that includes: a port to receive the incoming signal from the DUT on a channel of the test and measurement instrument; one or more analog to digital converters (ADCs) to convert the incoming signal from the DUT into a digital representation of the incoming signal; and one or more processors configured to execute code to cause the one or more processors to: characterize the incoming signal; apply a local GAN model residing on the test and measurement instrument to replicate the incoming signal with matching characteristics as a replica signal; and send any updates to the local GAN model to a central server.
Example 11 is the test and measurement instrument of Example 10, wherein the one or more processors are further configured to execute code to cause the one or more processors to send the replica signal to one or more databases.
Example 12 is the test and measurement instrument of any of Examples 1 through 11, wherein the one or more signal generators comprise an arbitrary waveform generator.
Example 13 is a method, comprising: receiving a request for a signal having a signal profile from a node in a test and measurement system; sending the signal profile and the request to one or more of generative adversarial network (GAN) models; receiving a matching signal profile that matches the signal profile from the one or more GAN models; and transmitting the matching signal profile to one or more signal generators to generate and transmit a matching signal.
Example 14 is the method of Example 13, wherein the signal profile includes information about one or more of an environment in which the node operates, metadata of the request, and a potential target of the matching signal.
Example 15 is the method of either of Examples 13 or 14, further comprising storing the matching signal in a database.
Example 16 is the method of Example15, accessing the database to determine if the signal profile exists in the database, and to send the signal profile from the database to the one or more GAN models.
Example 17 is the method of Example16, further comprising operating the one or more GAN models to produce the matching signal profile.
Example 18 is the method of any of Examples 13 through 17, further comprising distributing an updated GAN model resulting from the request to other nodes in a system in which the updated GAN model resides.
Example 19 is the method of any of Examples 13 through 18, wherein receiving the request for the signal comprising receiving an incoming signal from a device under test (DUT) at a sensor node.
Example 20 is the method of Example 19, wherein receiving the incoming signal at the sensor node further comprises: characterizing the incoming signal; applying a local GAN model residing on the node to replicate the incoming signal with matching characteristics as a replica signal; and sending any updates to the local GAN model to a central server.
Example 21 is the method of Example 20, further comprising sending the replica signal to one or more databases.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

1. A test and measurement system, comprising:
a plurality of nodes, one or more nodes comprising sensors configured to receive signals;
one or more generative adversarial network (GAN) models;
one or more signal generators configured to generate and transmit signals; and
one or more processors configured to execute code to cause the one or more processors to:
receive a request for a signal having a signal profile from a node of the plurality of nodes;
send the signal profile and the request to one of the one or more GAN models;
receive a matching signal profile that matches the signal profile; and
transmit the matching signal profile to one of the one or more signal generators to generate and transmit a matching signal.

2. The test and measurement system as claimed in claim 1, wherein the signal profile includes one or more of an environment in which a node of the plurality of nodes operates, metadata of the request, and a potential target of the matching signal.

3. The test and measurement system as claimed in claim 1, wherein the one or more processors are further configured to store the matching signal in a database.

4. The test and measurement system as claimed in claim 3, wherein the one or more processors are further configured to access the database to determine if the signal profile exists in the database, and to send the signal profile from the database to the one or more GAN models.

5. The test and measurement system as claimed in claim 1, wherein the one or more processors are further configured to operate the one or more GAN models to produce the matching signal profile.

6. The test and measurement system as claimed claim 1, wherein the one or more processors configured to operate the one or more GAN models comprises one or more processors on a node of the plurality of nodes that sent the request.

7. The test and measurement system as claimed in claim 1, wherein the one or more processors configured to operate the one or more GAN models comprises one or more processors on a central server in the test and measurement system.

8. The test and measurement system as claimed in claim 7, wherein the one or more processors on the central server are further configured to distribute an updated GAN model resulting from the request to the plurality of nodes.

9. The test and measurement system as claimed in claim 1, wherein one or more of the sensors receives an incoming signal from a device under test (DUT).

10. The test and measurement system as claimed in claim 9, wherein one or more of the sensors further comprises a test and measurement instrument that includes:
a port to receive the incoming signal from the DUT on a channel of the test and measurement instrument;
one or more analog to digital converters (ADCs) to convert the incoming signal from the DUT into a digital representation of the incoming signal; and
one or more processors configured to execute code to cause the one or more processors to:
characterize the incoming signal;
apply a local GAN model residing on the test and measurement instrument to replicate the incoming signal with matching characteristics as a replica signal; and
send any updates to the local GAN model to a central server.

11. The test and measurement instrument as claimed in claim 10, wherein the one or more processors are further configured to execute code to cause the one or more processors to send the replica signal to one or more databases.

12. The test and measurement instrument as claimed in claim 1, wherein the one or more signal generators comprise an arbitrary waveform generator.

13. A method, comprising:
receiving a request for a signal having a signal profile from a node in a test and measurement system;
sending the signal profile and the request to one or more of generative adversarial network (GAN) models;
receiving a matching signal profile that matches the signal profile from the one or more GAN models; and
transmitting the matching signal profile to one or more signal generators to generate and transmit a matching signal.

14. The method as claimed in claim 13, wherein the signal profile includes information about one or more of an environment in which the node operates, metadata of the request, and a potential target of the matching signal.

15. The method as claimed in claim 13, further comprising storing the matching signal in a database.

16. The method as claimed in claim 15, accessing the database to determine if the signal profile exists in the database, and to send the signal profile from the database to the one or more GAN models.

17. The method as claimed in claim 16, further comprising operating the one or more GAN models to produce the matching signal profile.

18. The method as claimed in claim 13, further comprising distributing an updated GAN model resulting from the request to other nodes in a system in which the updated GAN model resides.

19. The method as claimed in claim 13, wherein receiving the request for the signal comprising receiving an incoming signal from a device under test (DUT) at a sensor node.

20. The method as claimed in claim 19, wherein receiving the incoming signal at the sensor node further comprises:
characterizing the incoming signal;
applying a local GAN model residing on the node to replicate the incoming signal with matching characteristics as a replica signal; and
sending any updates to the local GAN model to a central server.

21. The method as claimed in claim 20, further comprising sending the replica signal to one or more databases.
